(19) United States
(12) Patent Application Publication
(10) Pub. No.: US 2026/0029482 A1
(43) Pub. Date: Jan. 29, 2026

(54) ELECTROCHEMICAL METHOD FOR STATE OF HEALTH ESTIMATION

(71) Applicant: Robert Bosch GmbH, Stuttgart (DE)

(72) Inventors: Shirin MEHRAZI, Sunnyvale, CA (US); Lei CHENG, Sunnyvale, CA (US); Jonathan BRAATEN, Sunnyvale, CA (US); Bjoern STUEHMEIER, Sunnyvale, CA (US); Alexander VAN BRUNT, Sunnyvale, CA (US); Nathan CRAIG, Sunnyvale, CA (US); Jake CHRISTENSEN, Elk Grove, CA (US)

(21) Appl. No.: 18/784,188

(22) Filed: Jul. 25, 2024

(51) Int. Cl. G01R 31/392; G01R 31/374; G01R 31/3842; G01R 31/389

(52) U.S. Cl. CPC G01R 31/392; G01R 31/374; G01R 31/3842; G01R 31/389

(57) ABSTRACT

An electrochemical method for state of degradation estimation. The method includes extracting capacitances from electrodes of a fuel cell stack at a bias potential at two or more aging characteristics during a fuel cell stack operation condition to obtain extracted capacitance signals. The method further includes determining a state of degradation of a component of the fuel cell stack in response to the extracted capacitances.

### TECHNICAL FIELD

The present disclosure relates to an electrochemical method for state of health estimation. The electrochemical method may determine a state of degradation of a fuel cell stack using extracted capacitance values from a fuel cell stack.

### BACKGROUND

One type of electrochemical cell is a device capable of generating electrical energy from chemical reactions (e.g., fuel cells). Fuel cells have shown promise as an alternative power source for vehicles and other transportation applications. Fuel cells operate with a renewable energy carrier, such as hydrogen. Fuel cells also operate without toxic emissions or greenhouse gases. An individual fuel cell includes a membrane electrode assembly (MEA) and two flow field plates. An individual fuel cell typically delivers 0.5 to 1.0 V. Individual fuel cells can be stacked together to form a fuel cell stack having higher voltage and power. One type of fuel cell is a proton exchange membrane fuel cell (PEMFC).

### SUMMARY

In an embodiment, an electrochemical method for state of degradation estimation is disclosed. The method includes extracting capacitances from electrodes of a fuel cell stack at a bias potential at two or more aging characteristics during a fuel cell stack operation condition to obtain extracted capacitance signals. The method further includes determining a state of degradation of a component of the fuel cell stack in response to the extracted capacitances.

In another embodiment, an electrochemical system for state of degradation estimation is disclosed. The system includes a fuel cell stack including electrodes, a power supply configured to hold a potential of the fuel cell stack constant, a direct current to direct current converter (DC/DC converter) configured to apply an alternating current to the fuel cell stack to extract electrode capacitances from the electrodes of the fuel cell stack. The electrochemical state of degradation estimation system further includes a vehicle computer system configured to determine a state of degradation of the fuel cell stack in response to the extracted capacitances. The vehicle computer system may include a vehicle computer and an electronic control unit (ECU). The vehicle computer may be programmed to analyze an impedance signal received from the DC/DC converter, estimate or identify a state of health (e.g., degradation), and send a signal to the ECU to control one or more components of the fuel cell stack.

In yet another embodiment, an electrochemical system for state of degradation estimation is disclosed. The system includes a fuel cell stack including individual fuel cells including electrodes. The system further includes a potentiostat connected to the fuel cell stack and configured to output current signals from the individual fuel cells. The system also includes a cell voltage monitor connected to the fuel cell stack and configured to output voltage signals from the individual fuel cells. The system also includes a vehicle computer system configured to obtain impedance spectra from the individual cells in response to the current signals and the voltage signals and to determine a state of degradation of the fuel cell stack in response to the impedance data. The vehicle computer may be programmed to analyze an impedance signal received from the DC/DC converter, estimate or identify a state of health (e.g., degradation), and send a signal to the ECU to control one or more components of the fuel cell stack.

### BRIEF DESCRIPTION OF THE DRAWINGS

FIG. 1 depicts a schematic, side view of certain components of an individual fuel cell 10 according to one embodiment.

FIG. 2 depicts a flowchart including a method for analyzing an impedance response using a DC/DC converter.

FIGS. 3A, 3B, 3C, 3D, and 3E depict graphs of capacitance in F/cm² as a function of Zᵣₑₐₗ (i.e., the real part of resistance) minus HFR (i.e., high frequency resistance) values at a bias potential of 0.2V and 0.45V for commercial MEA number 1 at BOL (i.e., beginning of life) and aging characterization intervals of 250 cycles, 500 cycles, 1,000 cycles, and 2,000 cycles, respectively.

FIGS. 4A, 4B, 4C, 4D, and 4E depict graphs of capacitance in F/cm² as a function of Zᵣₑₐₗ minus HFR values at a bias potential of 0.2V and 0.45V for commercial MEA number 2 at BOL and aging characterization intervals of 1,500 cycles, 4,500 cycles, 12,500 cycles, and 28,500 cycles, respectively.

FIGS. 5A and 5B depict a graph showing a correlation (i.e., a linear correlation) between capacitance extracted from PEIS spectra at 0.2V and 0.45V bias potentials and ECSA extracted from the corresponding cyclic voltammogram for MEA number 1 and MEA number 2, respectively.

### DETAILED DESCRIPTION

Embodiments of the present disclosure are described herein. It is to be understood, however, that the disclosed embodiments are merely examples and other embodiments may take various and alternative forms. The figures are not necessarily to scale; some features could be exaggerated or minimized to show details of particular components. Therefore, specific structural and functional details disclosed herein are not to be interpreted as limiting, but merely as a representative basis for teaching one skilled in the art to variously employ the present embodiments. As those of ordinary skill in the art will understand, various features illustrated and described with reference to any one of the figures may be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

Except in the examples, or where otherwise expressly indicated, all numerical quantities in this description indicating amounts of material or conditions of reaction and/or use are to be understood as modified by the word “about” in describing the broadest scope of the invention. Practice within the numerical limits stated is generally preferred. Also, unless expressly stated to the contrary: percent, “parts of,” and ratio values are by weight; the description of a group or class of materials as suitable or preferred for a given purpose in connection with the invention implies that mixtures of any two or more of the members of the group or class are equally suitable or preferred; description of constituents in chemical terms refers to the constituents at the time of addition to any combination specified in the description, and does not necessarily preclude chemical interactions among the constituents of a mixture once mixed.

The first definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

It must also be noted that, as used in the specification and the appended claims, the singular form “a,” “an,” and “the” comprise plural referents unless the context clearly indicates otherwise. For example, reference to a component in the singular is intended to comprise a plurality of components.

As used herein, the term “substantially,” “generally,” or “about” means that the amount or value in question may be the specific value designated or some other value in its neighborhood. Generally, the term “about” denoting a certain value is intended to denote a range within ±5% of the value. As one example, the phrase “about 100” denotes a range of 100±5, i.e. the range from 95 to 105. Generally, when the term “about” is used, it can be expected that similar results or effects according to the invention can be obtained within a range of ±5% of the indicated value. The term “substantially” may modify a value or relative characteristic disclosed or claimed in the present disclosure. In such instances, “substantially” may signify that the value or relative characteristic it modifies is within ±0%, 0.1%, 0.5%, 1%, 2%, 3%, 4%, 5% or 10% of the value or relative characteristic.

It should also be appreciated that integer ranges explicitly include all intervening integers. For example, the integer range 1 to 10 explicitly includes 1, 2, 3, 4, 5, 6, 7, 8, 9, and 10. Similarly, the range 1 to 100 includes 1, 2, 3, 4, . . . 97, 98, 99, 100. Similarly, when any range is called for, intervening numbers that are increments of the difference between the upper limit and the lower limit divided by 10 can be taken as alternative upper or lower limits. For example, if the range is 1.1 to 2.1 the following numbers 1.2, 1.3, 1.4, 1.5, 1.6, 1.7, 1.8, 1.9, and 2.0 can be selected as lower or upper limits.

As used herein, the term “and/or” means that either all or only one of the elements of said group may be present. For example, “A and/or B” means “only A, or only B, or both A and B”. In the case of “only A”, the term also covers the possibility that B is absent, i.e., “only A, but not B”.

It is also to be understood that this invention is not limited to the specific embodiments and methods described below, as specific components and/or conditions may, of course, vary. Furthermore, the terminology used herein is used only for the purpose of describing particular embodiments of the present invention and is not intended to be limiting in any way.

The term “comprising” is synonymous with “including,” “having,” “containing,” or “characterized by.” These terms are inclusive and open-ended and do not exclude additional, unrecited elements or method steps.

The phrase “consisting of” excludes any element, step, or ingredient not specified in the claim. When this phrase appears in a clause of the body of a claim, rather than immediately following the preamble, it limits only the element set forth in that clause; other elements are not excluded from the claim as a whole.

The phrase “consisting essentially of” limits the scope of a claim to the specified materials or steps, plus those that do not materially affect the basic and novel characteristic(s) of the claimed subject matter.

With respect to the terms “comprising,” “consisting of,” and “consisting essentially of,” where one of these three terms is used herein, the presently disclosed and claimed subject matter can include the use of either of the other two terms.

The term “one or more” means “at least one” and the term “at least one” means “one or more.” The terms “one or more” and “at least one” include “plurality” as a subset.

The description of a group or class of materials as suitable for a given purpose in connection with one or more embodiments implies that mixtures of any two or more of the members of the group or class are suitable. Description of constituents in chemical terms refers to the constituents at the time of addition to any combination specified in the description and does not necessarily preclude chemical interactions among constituents of the mixture once mixed. First definition of an acronym or other abbreviation applies to all subsequent uses herein of the same abbreviation and applies mutatis mutandis to normal grammatical variations of the initially defined abbreviation. Unless expressly stated to the contrary, measurement of a property is determined by the same technique as previously or later referenced for the same property.

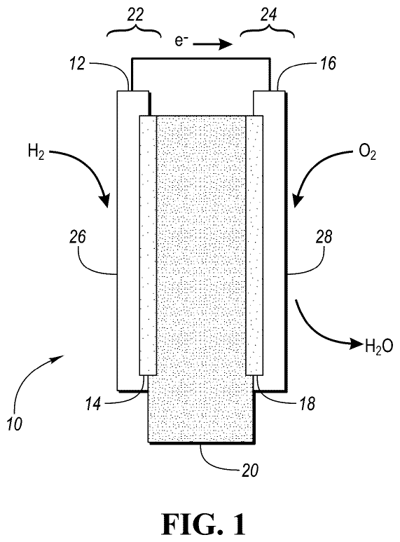

One type of fuel cell is a proton exchange membrane fuel cell (PEMFC). The PEMFC may include a fuel cell stack comprised of several individual fuel cells. FIG. 1 depicts a schematic, side view of certain components of individual fuel cell 10 according to one embodiment. As shown in FIG. 1, fuel cell 10 includes anode catalyst support 12 coated with anode catalyst layer 14 formed of an anode catalyst material and cathode catalyst support 16 coated with cathode catalyst layer 18 formed of a cathode catalyst material. Polymer electrolyte membrane (PEM) 20 extends between anode catalyst support 12 and cathode catalyst support 16. PEM 20 may be referred to as an ionomer membrane. Anode catalyst layer 14 is positioned between anode catalyst support 12 and PEM 20. Cathode catalyst layer 18 is positioned between cathode catalyst support 16 and PEM 20. Anode 22 may generally refer to anode catalyst support 12 and anode catalyst layer 14. Anode 22 may be referred to as an anode electrode. Cathode 24 may generally refer to cathode catalyst support 16 and cathode catalyst layer 18. Cathode 24 may be referred to as a cathode electrode. The anode electrode and the cathode electrode may be collectively referred to as electrodes of a fuel cell. Fuel cell 10 also includes first and second gas diffusion layers (GDLs) (not shown).

In an individual fuel cell of a fuel cell stack, cyclic voltammetry (e.g., direct current (DC) voltage sweep) may be utilized in the calculation of the electrochemically active surface area (ECSA) of the individual fuel cell. Cyclic voltammetry may be employed in connection with hydrogen adsorption-desorption on a catalyst surface of a fuel cell electrode to determine a charge used to calculate ECSA.

However, this application of cyclic voltammetry applies to individual fuel cells and not a fuel cell stack with multiple individual cells in a series configuration. From cyclic voltammetry, it is known that a hydrogen adsorption-desorption on a platinum catalyst surface, which may occur within a voltage range of 0.0 to 0.3V, may result in a pseudo capacitance in addition to an existing double-layer capacitance at an ionomer-catalyst interface. In view of this pseudo capacitance, cathode electrode capacitance may be considered as a state of health measurement, thereby enabling the use of fuel cell stack level methods to evaluate total cathode electrode capacitance in the fuel cell stack. Potentiostatic or galvanostatic electrochemical impedance measurements (PEIS/GEIS) with a small amplitude of an alternating current (AC) may be used to measure fuel cell stack impedance and extract capacitance from an electrochemical impedance spectroscopy (EIS) spectrum. The DC potential may be held constant. The current response is measured over a range of frequencies to obtain an impedance spectrum.

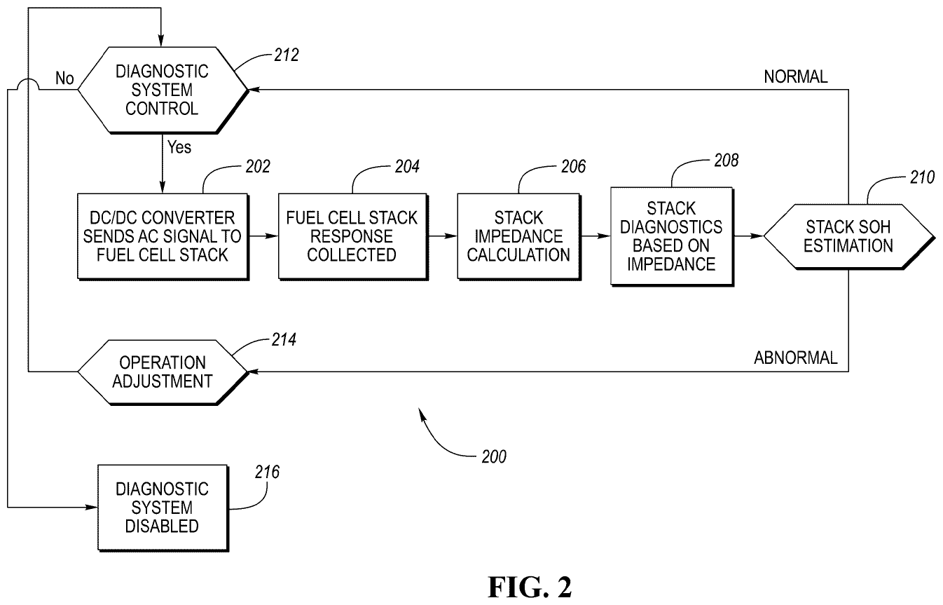

An AC for EIS may be applied to a fuel cell stack using direct current/direct current (DC/DC) converters in a fuel cell stack system. The extracted capacitance values from the impedance spectra may be correlated to an ECSA or be directly used as a state of health measurement. FIG. 2 depicts a flowchart including a method for analyzing an impedance response using a DC/DC converter. The operations depicted in flowchart 10 may be rearranged, omitted, augmented, and/or modified depending on the implementation of the method for analyzing an impedance response to determine a state of health measurement.

As depicted in operation 202, the method of flowchart 200 includes a DC/DC converter sending an AC signal to a fuel cell stack. As depicted in operation 204, the method of flowchart 200 includes collecting a response (e.g., an electrical response) to the AC signal sent to the fuel cell stack. The response may be collected by an electrical sensor. As depicted in operation 206, the method of flowchart 200 includes calculating a fuel cell stack impedance based on the response collected in operation 204. As depicted in operation 208, the method of flowchart 200 includes performing fuel cell stack diagnostics (e.g., a fuel cell stack state of health estimation) based on the fuel cell stack impedance calculated in operation 206. The calculating and/or performing step are carried out by a processing device, controller, or computer, which can include any existing programmable electronic control unit or dedicated electronic control unit.

As depicted in operation 210, the method depicted in flowchart 200 includes estimating a fuel cell stack state of health based on the fuel cell impedance. If the estimated fuel cell stack state of health is normal (e.g., indicating operation not leading to greater than normal degradation of the fuel cell stack), then control of the method is passed to a diagnostic system control module depicted by operation 212. If the estimated fuel cell stack state of health is abnormal (e.g., indicating operation leading to greater than normal degradation of the fuel cell stack), then control of the method is passed to operation 214.

As depicted in operation 214, the method of flowchart 200 attempts an operation adjustment in response to the abnormal fuel cell stack state of health condition. After the adjustment is performed, then control of the method depicted in flowchart 200 is passed to diagnostic system control module depicted by operation 212.

The ECSA of a cathode electrode in a fuel cell may be used as a state of health assessment for durability assessments of fuel cells to determine operational viability of the fuel cell. Catalyst degradation during fuel cell operation may result in the loss of ECSA. The loss of ECSA may be used for fuel cell stack lifetime estimations. A cathode catalyst layer may degrade due to catalyst metal dissolution and redeposition, carbon, corrosion, and/or ionomer degradation. One or more embodiments disclose a method of measuring a state of health of a fuel cell stack based on an electrochemical impedance-based assessment of a cathode electrode capacitance.

In one or more embodiments, a fuel cell stack potential may be held at a constant value using an external power source such that all the individual fuel cells in the fuel cell stack are at a relevant potential range for electrochemical adsorption-desorption of hydrogen on the catalyst surface. With the constant fuel cell stack potential, a pseudo capacitance from the hydrogen adsorption-desorption on the catalyst surface contributes to the capacitance of the entire electrode, thereby permitting the determination of a loss in an active area of the catalyst. A linear correlation may be determined between an electrode capacitance assessment an ECSA measurement from cyclic voltammetry. The method of one or more embodiments may be validated using an individual fuel cell setup.

In one or more embodiments, a DC/DC converter in a fuel cell stack (e.g., PEMFC) is used to apply AC current to the fuel cell stack and to extract an electrode capacitance from corresponding EIS spectra. In one or more embodiments, the capacitance of the cathode electrode is extracted from potentiostatic EIS spectra and has a linear correlation with an ECSA extracted from cyclic voltammetry. The AC impedance measurement may be used for an entire fuel cell.

The AC impedance measurement may be performed on a fuel cell stack during a fuel cell stack operation condition. The fuel cell stack operation condition may be a fuel cell stack with a nitrogen flow on the cathode side of the fuel cell stack. The fuel cell stack operation condition may be a fuel cell stack under a hydrogen anode environment. The fuel cell stack operation condition may be a complete or partial bleed down of air during the shutdown procedure. The fuel cell stack operation condition may be an open circuit voltage condition (e.g., at, near, or close to an open voltage condition). The fuel cell stack operation condition may be a low power load condition (e.g., a current density per unit active area of less than 0.2 A/cm² or 0.1 A/cm²).

Using an external power supply, a fuel cell stack potential can be held constant such that each fuel cell has a potential range. The potential range may be 0.0 to 0.3V or 0.0 to 0.4V. The potential range may be set as a range in which hydrogen adsorption-desorption occurs on a catalyst surface (e.g., a Pt surface). In one or more embodiments, a single impedance measurement from the entire fuel cell stack may include the cathode capacitances from the individual cells (e.g., all of the individual cells). This capacitance measurement is expected to decrease as a function of aging of the fuel cell stack.

One or more cell voltage monitors (CVMs) may be attached to individual fuel cells during a vehicle service or diagnostic cycle. During the vehicle service or diagnostic cycle, individual impedance spectra of individual cells (e.g., each of the individual cells) may be achieved using one or more auxiliary channels of a potentiostat. The potentiostat may be configured to control and to measure potentials (i.e., voltages) of individual fuel cells. The potentiostat may be used as part of a system to obtain potentiostatic impedance spectroscopy from the individual fuel cells (e.g., each of the individual cells). The potentiostatic impedance spectroscopy may be used to characterize a state of degradation of a fuel cell.

The state of degradation and related data may be input into an algorithm configured to determine a predicted lifetime of the fuel cell state. The predicted lifetime may be compared to the current state of degradation to determine one or more optimum operational conditions to achieve a target lifetime using milder aging conditions.

In one example according to one embodiment, potentiostatic electrochemical impedance spectroscopy (PEIS) at bias potentials of about 0.2V (hydrogen adsorption-desorption) and about 0.45V (double layer capacitance; no impact from catalyst (e.g., Pt) surface capacitance) have been performed on individual cells of two different membrane electrode assemblies (MEA) (i.e., commercial MEA number 1 and commercial MEA number 2).

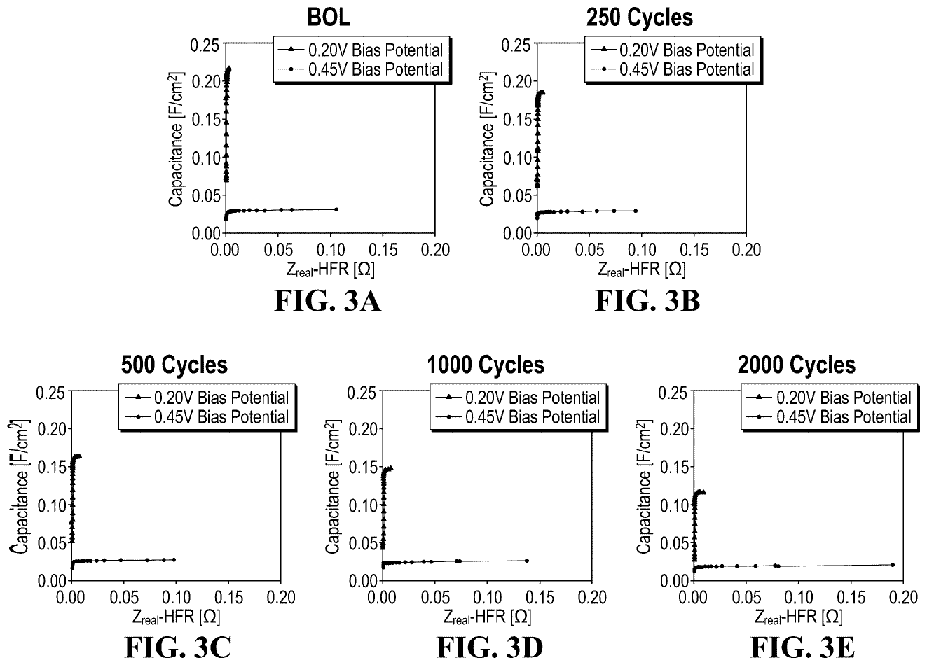

Capacitance values were extracted from impedance spectra for commercial MEA number 1. FIGS. 3A, 3B, 3C, 3D, and 3E depict graphs of capacitance in F/cm² as a function of Zᵣₑₐₗ (i.e., the real part of resistance) minus HFR (i.e., high frequency resistance) values at a bias potential of 0.2V and 0.45V for commercial MEA number 1 at BOL (i.e., beginning of life) and aging characterization intervals of 250 cycles, 500 cycles, 1,000 cycles, and 2,000 cycles, respectively. The extracted capacitance values were degraded by square wave voltage cycling in an individual cell fuel cell setup.

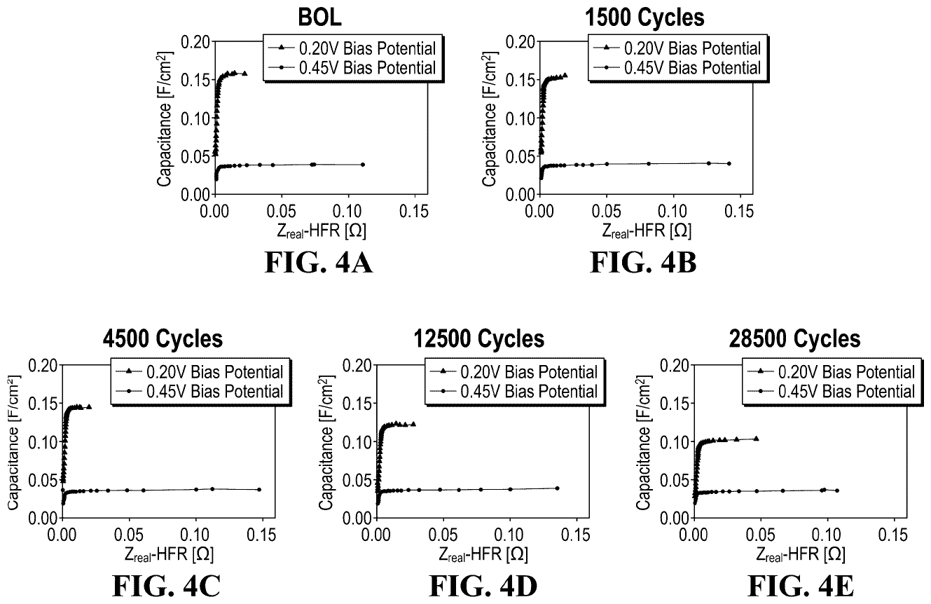

Capacitance values were extracted from impedance spectra for commercial MEA number 2. FIGS. 4A, 4B, 4C, 4D, and 4E depict graphs of capacitance in F/cm² as a function of Zᵣₑₐₗ minus HFR values at a bias potential of 0.2V and 0.45V for commercial MEA number 2 at BOL and aging characterization intervals of 1,500 cycles, 4,500 cycles, 12,500 cycles, and 28,500 cycles, respectively. The extracted capacitance values were degraded by square wave voltage cycling in an individual cell fuel cell setup.

As depicted by FIGS. 3A to 3E and FIGS. 4A to 4E, the load profile patterns and the total cycle numbers are different for MEA number 1 and MEA number 2. The method of one or more embodiments was tested on individual fuel cells of various MEAs at different states of degradation. In FIGS. 3A to 3E and FIGS. 4A to 4E, the red values were extracted capacitance values from PEIS measurement at a platinum surface impacted potential of 0.2V, and the blue values were extracted capacitance values from PEIS measurements at a double layer capacitance dominant potential of 0.45V. As shown in these figures, the reduction in capacitance with aging was captured by PEIS at 0.2V and indicates a sign of the loss of active surface area. Capacitance values extracted from PEIS of 0.45V remained similar from BOL to load cycling, indicating no significant change in the ionomer structure of the electrode.

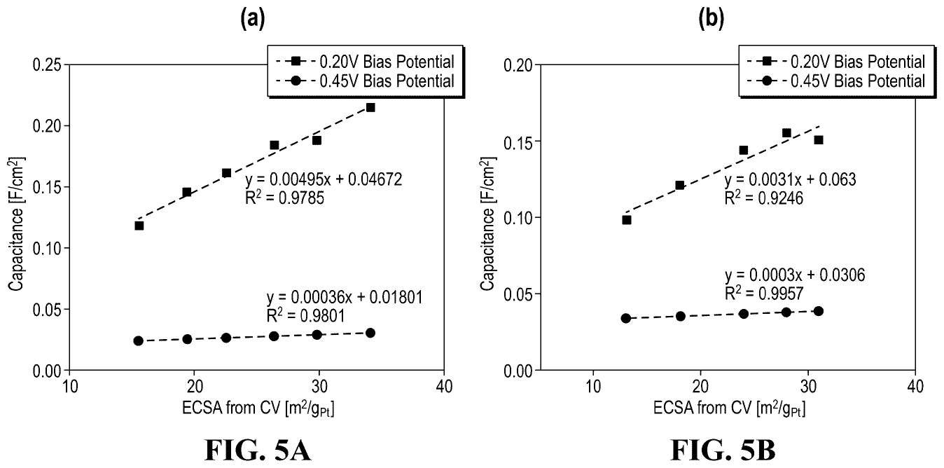

FIGS. 5A and 5B depict a graph showing a correlation between capacitance extracted from PEIS spectra at 0.2V and 0.45V bias potentials and ECSA extracted from the corresponding cyclic voltammogram for MEA number 1 and MEA number 2, respectively. In both cases, a linear correlation between a cathode electrode capacitance from PEIS at 0.2V and the ECSA from cyclic voltammetry was found. The electronic properties measured by a voltage sweep (e.g., DC voltage sweep) may be used to quantify one or more states of degradation.

A limiting capacitance of a cathode electrode may be obtained by single frequency PEIS measurements within a frequency range (e.g., 0.1 to 50 Hz). The frequency range may be changed based on stack size. The frequency of a voltage change in a drive cycle may be within a characteristic frequency range to measure a state of health in the form of the capacitance of the electrode.

The linear correlation between ECSA and capacitance may be measured on an individual cell and a correlation factor may be applied to this measurement to obtain the linear correlation for the entire fuel cell stack. The correlation factor may be obtained from the fuel cell stack manufacturer.

In one or more embodiments, a correlation between ECSA measured by cyclic voltammetry and an electrode's capacitance measured by PEIS is a function of one or more operating conditions (e.g., temperature, pressure, relative humidity, etc.). The correlation may be a linear correlation. Sensors may be used to obtain one or more operational values. Examples of such sensors include temperature sensors, pressure sensors, and relative humidity sensors. A multidimensional lookup table or model may be used to account for the one or more operating conditions.

The processes, methods, or algorithms disclosed herein may be deliverable to or implemented by a processing device, controller, or computer, which may include any existing programmable electronic control unit or dedicated electronic control unit. Similarly, the processes, methods, or algorithms may be stored as data and instructions executable by a controller or computer in many forms including, but not limited to, information permanently stored on non-writable storage media such as ROM devices and information alterably stored on writeable storage media such as floppy disks, magnetic tapes, CDs, RAM devices, and other magnetic and optical media. The processes, methods, or algorithms may also be implemented in a software executable object. Alternatively, the processes, methods, or algorithms may be embodied in whole or in part using suitable hardware components, such as Application Specific Integrated Circuits (ASICs), Field-Programmable Gate Arrays (FPGAs), state machines, controllers or other hardware components or devices, or a combination of hardware, software, and firmware components.

In one or more embodiments, a vehicle computer system may be connected to a fuel cell stack of the vehicle. The vehicle computer system may include a vehicle computer and an electronic control unit (ECU). The vehicle computer may be programmed to analyze an impedance signal received from a DC/DC converter, estimate or identify a state of health (e.g., degradation), and send a signal to the ECU to control one or more components of the fuel cell stack. The vehicle computer system and network connection system(s) may be configured such that a state of health assessment may be communicated online and shared with other computing resources. The state of health assessment methods of one or more embodiments may be used during vehicle service where measurements associated with the assessment may be performed by an external power source like a potentiostat.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further embodiments of the invention that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, to the extent any embodiments are described as less desirable than other embodiments or prior art implementations with respect to one or more characteristics, these embodiments are not outside the scope of the disclosure and can be desirable for particular applications.

What is claimed is:

1. An electrochemical method for state of degradation estimation comprising:
extracting capacitances from electrodes of a fuel cell stack at a bias potential at two or more aging characteristics during a fuel cell stack operation condition to obtain extracted capacitance signals; and
determining a state of degradation of a component of the fuel cell stack in response to the extracted capacitances.

2. The electrochemical method of claim 1, wherein the component is an electrode surface and the state of degradation is catalyst degradation.

3. The electrochemical method of claim 1, wherein the component is a carbon catalyst electrode support and the state of degradation is carbon corrosion.

4. The electrochemical method of claim 1, wherein the component is an ionomer material and the state of degradation is ionomer degradation.

5. The electrochemical method of claim 1, wherein the extracting step includes obtaining electrochemical impedance spectroscopy of the fuel cell stack.

6. The electrochemical method of claim 5 further comprising extracting an overall fuel cell stack capacitance for the electrochemical impedance spectroscopy.

7. The electrochemical method of claim 1, wherein the fuel cell stack operation condition is a nitrogen flow condition on a cathode side of the fuel cell stack, a hydrogen flow condition on an anode side of the fuel cell stack, after air bleed down during shutdown of the fuel cell stack, an open circuit voltage condition of the fuel cell stack, or a low power load condition of the fuel cell stack.

8. The electrochemical method of claim 1, wherein the bias potential is 0.0 to 0.4V such that a hydrogen adsorption-desorption occurs at catalyst surfaces of the electrodes.

9. The electrochemical method of claim 1, wherein the two or more aging characteristics are beginning of life (BOL) and a number of aging cycles.

10. The electrochemical method of claim 1 further comprising determining an electrochemically active surface area (ECSA) of the fuel cell stack in response to a correlation between the ECSA and the extracted capacitances.

11. The electrochemical method of claim 10, wherein the correlation is a linear relationship between a cyclic voltammetry ECSA and the extracted capacitances.

12. The electrochemical method of claim 11, wherein the linear relationship is a function of one or more operational conditions.

13. The electrochemical method of claim 11 further comprising measuring the linear relationship between the cyclic voltammetry ECSA and the extracted capacitances on an individual cell within the fuel cell stack and the correlation includes a factor for the fuel cell stack applied to the linear relationship.

14. The electrochemical method of claim 1 further comprising determining a residual life of the fuel cell stack in response to the extracted capacitances.

15. The electrochemical method of claim 14 further comprising determining one or more optimum operating conditions to achieve a target life time longer than the residual life.

16. An electrochemical system for state of degradation estimation, the system comprising:
a fuel cell stack including electrodes;
a power supply configured to hold a potential of the fuel cell stack constant;
a direct current to direct current converter (DC/DC converter) configured to apply an alternating current to the fuel cell stack to extract electrode capacitances from the electrodes of the fuel cell stack; and
a vehicle computer system configured to determine a state of degradation of the fuel cell stack in response to the extracted capacitances.

17. An electrochemical system for state of degradation estimation, the system comprising:
a fuel cell stack including individual fuel cells including electrodes;
a potentiostat connected to the fuel cell stack and configured to output current signals from the individual fuel cells;
a cell voltage monitor connected to the fuel cell stack and configured to output voltage signals from the individual fuel cells; and
a vehicle computer system configured to obtain impedance spectra from the individual cells in response to the current signals and the voltage signals and to determine a state of degradation of the fuel cell stack in response to the impedance spectra.

18. The electrochemical system of claim 17, wherein the fuel cell stack is a group of individual cells or all of the individual cells.

19. The electrochemical system of claim 17, wherein the potentiostat includes one or more auxiliary channels.

20. The electrochemical system of claim 17, wherein the impedance spectra are potentiostatic electrochemical impedance spectra.
